(19) United States
(12) Patent Application Publication
(10) Pub. No.: US 2026/0042961 A1
(43) Pub. Date: Feb. 12, 2026

(54) PHOSPHOR PLATE

(71) Applicant: CoorsTek GK, Tokyo (JP)

(72) Inventors: Kosuke KIMURA, Kanagawa (JP); Masaki IRIE, Kanagawa (JP)

(21) Appl. No.: 18/979,422

(22) Filed: Dec. 12, 2024

(30) Foreign Application Priority Data
Aug. 8, 2024 (JP) 2024-131735
Oct. 24, 2024 (JP) 2024-187552

(51) Int. Cl. C09K 11/77; H01S 5/06; H10H 20/851

(52) U.S. Cl. CPC C09K 11/7706; H10H 20/8513; H01S 5/0611

(57) ABSTRACT

A phosphor plate includes a plate-shaped sintered body having a light incident surface and a light exit surface, and a glass coating layer provided at the light exit surface, and the sintered body includes (Y_{1-x-y}, Gdₓ, Ce_{y})₃Al₅O₁₂ particles, where x and y fall within ranges 0.018≤x≤0.054 and 0.018≤y≤0.025, and Al₂O₃ particles, the (Y_{1-x-y}, Gdₓ, Ce_{y})₃Al₅O₁₂ particles and the Al₂O₃ particles have an overall average particle diameter of 3.0 μm to 5.0 μm, the (Y_{1-x-y}, Gdₓ, Ce_{y})₃Al₅O₁₂ particles have a concentration of 15 vol % to 25 vol % with respect to a total amount 100 vol % of the (Y_{1-x-y}, Gdₓ, Ce_{y})₃Al₅O₁₂ particles and the Al₂O₃ particles, the sintered body has a thickness of 90 μm to 160 μm.

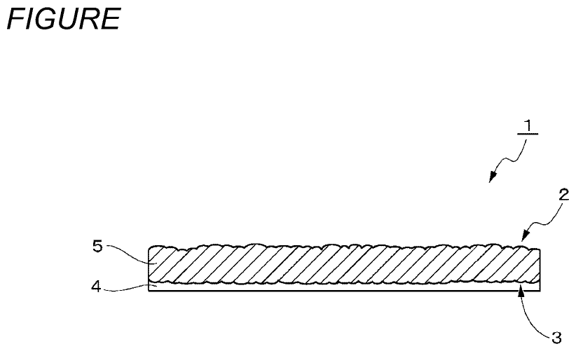

### CROSS-REFERENCE TO RELATED APPLICATIONS

This application is based on and claims priority under 35 USC 119 from Japanese Patent Application No. 2024-131735 filed on Aug. 8, 2024, and Japanese Patent Application No. 2024-187552 filed on Oct. 24, 2024.

### TECHNICAL FIELD

The present invention relates to a ceramic phosphor plate for obtaining white light by converting a wavelength of light emitted from a light emitting diode (LED) or a laser diode (LD).

### BACKGROUND ART

LEDs and LDs have the advantages of a longer life and lower power consumption than fluorescent lamps. Therefore, the LEDs and LDs are increasingly being used widely as illumination lights for backlights and display panels of small displays, panels for large displays, car headlights, and other general illumination fixtures.

Among white light lamps that use LEDs and LDs to produce white light, the most promising applications for illumination fixtures that require higher heat resistance and higher durability, such as car headlights, are those in which a blue LED chip or LD chip is combined with various ceramic phosphors. In the case where a blue LED is used as a light source, the light emitted from the blue LED excites a yellow phosphor in the ceramic phosphor, and white light is emitted by additively mixing blue and yellow.

As such a ceramic phosphor, for example, JP2022-104527A discloses, as a phosphor plate that emits white light large in luminous flux, small in emission efficiency reduction due to a temperature increase, and small in chromaticity difference, a phosphor plate including a sintered body made from (Y_{1-x-y}, Gdₓ, Ce_{y})₃Al₅O₁₂ particles (where 0.07≤x≤0.11 and 0.010≤y≤0.015) and Al₂O₃ particles, in which the (Y_{1-x-y}, Gdₓ, Ce_{y})₃Al₅O₁₂ particles has an average particle diameter of 4 μm or more and 6 μm or less, the (Y_{1-x-y}, Gdₓ, Ce_{y})₃Al₅O₁₂ particles has a concentration of 20 vol % or more and 30 vol % or less with respect to a total amount 100 vol % of the (Y_{1-x-y}, Gdₓ, Ce_{y})₃Al₅O₁₂ particles and the Al₂O₃ particles, a ratio (Al₂O₃/(Y_{1-x-y}, Gdₓ, Ce_{y})₃Al₅O₁₂) of an average particle diameter of the Al₂O₃ particles to the average particle diameter of the (Y_{1-x-y}, Gdₓ, Ce_{y})₃Al₅O₁₂ particles is 1 or more and 2 or less, and the sintered body has an overall thickness of 150 μm or more and 250 μm or less.

In addition, in order to improve reliability and light extraction efficiency, there is an invention in JP2022-41839A as a wavelength conversion element for forming a reflective layer or an anti-reflective film on a wavelength conversion layer. JP2022-41839A discloses a wavelength conversion element including: a wavelength conversion layer that converts light having a first wavelength into light having a second wavelength; a flattened layer having a surface roughness smaller than that of the wavelength conversion layer, on at least one surface of the wavelength conversion layer; and an anti-reflective film on the flattened layer to prevent reflection of at least a portion of the light having a first wavelength or the light having a second wavelength. In addition, JP2022-41839A discloses that a glass layer is used as the flattened layer, and a surface roughness Ra of the glass layer is preferably 100 nm (0.1 μm) or less, more preferably 10 nm (0.01 μm) or less, and still more preferably 5 nm (0.005 μm) or less. It is also disclosed that by having such a flattened layer on the surface of the wavelength conversion layer made from a sintered phosphor, voids on the surface of the wavelength conversion layer are filled with the flattened layer, and an anti-reflective film that matches a refractive index of the flattened layer can be formed, thereby improving the light extraction efficiency.

### SUMMARY OF INVENTION

In recent years, in white light lamps using a blue LED or LD, various studies have been conducted on improvements to LED chips, LD chips, and phosphor materials in order to increase the luminous flux even slightly. The phosphor plate disclosed in JP2022-104527A does indeed provide a reasonable improvement in luminous flux, but it does not fully meet recent demands. In light of such a background, an object of the present invention is to provide a phosphor plate that can provide a higher luminous flux in a white light lamp using a blue LED or LD.

A phosphor plate according to an aspect of the present invention includes: a plate-shaped sintered body having a light incident surface that is to receive light from a light source and a light exit surface that is disposed opposite to the light incident surface and that is to emit the light received at the light incident surface; and a glass coating layer provided at the light exit surface of the sintered body, wherein the sintered body comprises (Y_{1-x-y}, Gdₓ, Ce_{y})₃Al₅O₁₂ particles, where x and y fall within ranges 0.018≤x≤0.054 and 0.018≤y≤0.025, and Al₂O₃ particles, the (Y_{1-x-y}, Gdₓ, Ce_{y})₃Al₅O₁₂ particles and the Al₂O₃ particles have an overall average particle diameter of 3.0 μm or more and 5.0 μm or less, the (Y_{1-x-y}, Gdₓ, Ce_{y})₃Al₅O₁₂ particles have a concentration of 15 vol % or more and 25 vol % or less with respect to a total amount 100 vol % of the (Y_{1-x-y}, Gdₓ, Ce_{y})₃Al₅O₁₂ particles and the Al₂O₃ particles, the sintered body has a thickness of 90 μm or more and 160 μm or less, the glass coating layer is formed from an inorganic glass coating material, and a surface of the glass coating layer has a surface roughness Ra of 0.05 μm or more and 0.4 μm or less.

According to the present invention, it is possible to provide a phosphor plate that can provide a higher luminous flux in a white light lamp using a blue LED or LD.

### BRIEF DESCRIPTION OF DRAWING

The FIGURE is a diagram showing a phosphor plate according to one embodiment of the present invention.

### DETAILED DESCRIPTION OF THE INVENTION

Hereinafter, a phosphor plate according to the present invention will be described in detail with reference to the FIGURE.

A phosphor plate 1 according to the present invention includes: a plate-shaped sintered body 5 having a light incident surface 2 that is to receive light from a light source and a light exit surface 3 that is disposed opposite to the light incident surface 2 and that is to emit the light received at the light incident surface 2; and a glass coating layer 4 formed on the light exit surface 3 of the sintered body 5.

The plate-shaped sintered body 5 in the phosphor plate 1 is made from (Y_{1-x-y}, Gdₓ, Ce_{y})₃Al₅O₁₂ particles (hereinafter also referred to as “YAG-based particles”) and Al₂O₃ particles, the (Y_{1-x-y}, Gdₓ, Ce_{y})₃Al₅O₁₂ particles and the Al₂O₃ particles have an overall average particle diameter of 3.0 μm or more and 5.0 μm or less, and a Gd concentration (x) and a Ce concentration (y) in the YAG-based particles are adjusted to 0.018≤x≤0.054 and 0.018≤y≤0.025. When the sintered body 5 made from such a composite material and having the specific overall average particle diameter is made to have a good internal light scattering property, the Ce concentration (y) in the YAG-based particles is made higher than that in the related art, and the Gd concentration (x) is made lower than that in the related art, conversion efficiency from blue light to yellow light can be increased, and the thickness of the sintered body 5 can be reduced to 90 μm or more and 160 μm or less, and as a result, the luminous flux can be increased than that in the conventional art. The term “overall average particle diameter” used herein refers to an average particle diameter calculated from both of the YAG-based particles and the Al₂O₃ particles. This calculation considers every YAG-based and Al₂O₃ particles in the plate-shaped sintered body, irrespective of their proportions and individual sizes. Thus, it represents a measure of the collective average diameter of these two types of particles, not the average diameter of either particle type individually.

Note that, the luminous flux in the present specification refers to the brightness of white light, and refers to the brightness of white light produced by additive color mixing when a blue LED chip is mounted in a light emitting device and the phosphor plate 1 is irradiated with a blue LED to emit fluorescent light.

In the case where the overall average particle diameter of the (Y_{1-x-y}, Gdₓ, Ce_{y})₃Al₅O₁₂ particles and the Al₂O₃ particles is 3.0 μm or more and 5.0 μm or less and the thickness of the sintered body 5 is reduced to 90 μm or more and 160 μm or less, when the Ce concentration (y) is less than 0.018 and the Gd concentration (x) is more than 0.054, the conversion efficiency from blue light to yellow light decreases, resulting in a bluish white color. In addition, when the Ce concentration (y) is more than 0.025 and the Gd concentration (x) is less than 0.018, the color becomes yellowish white.

When 0.018≤x≤0.054 and 0.018≤y≤0.025 in the YAG-based particles, the overall average particle diameter of the YAG-based particles and the Al₂O₃ particles is 3.0 μm or more and 5.0 μm or less, and the thickness of the sintered body 5 is 90 μm or more and 160 μm or less, it is possible to produce white light having few other color shades (high whiteness) and increase the luminous flux.

In particular, when the Gd concentration (x) is 0.054 or less and an amount of Gd that causes high temperature degradation is reduced, a temperature characteristic can be improved. Note that, the temperature characteristic refers to the temperature dependency of the wavelength conversion efficiency, and a decrease in temperature characteristic refers to a decrease in wavelength conversion efficiency with a temperature increase.

In the phosphor plate 1 according to the present invention, a ratio of the Gd concentration (x) to the Ce concentration (y) in the phosphor plate 1 is preferably 0.9 or more and 2.2 or less. When the ratio is within this range, a phosphor plate having higher whiteness is obtained.

Here, the temperature characteristic is a value obtained by setting the phosphor plate 1 (10 mmx 10 mm) at the center of a 4-inch integrating sphere having a heater, irradiating the integrating sphere with excitation light in a wavelength range 450 nm±1 nm in the same manner as in fluorescence wavelength measurement, measuring quantum efficiency at 25° C. and 200° C. from an emission spectrum of the phosphor plate 1, and dividing the quantum efficiency at 200° C. by the quantum efficiency at 25° C. In addition, the Gd concentration (x) and the Ce concentration (y) in the (Y_{1-x-y}, Gdₓ, Ce_{y})₃Al₅O₁₂ particles in the plate-shaped sintered body 5 can be measured by ICP-AES (Inductively Coupled Plasma Atomic emission spectrometry).

When the overall average particle diameter of the YAG-based particles and the Al₂O₃ particles is less than 3.0 μm, there are too many grain boundaries and no sufficient luminous flux is obtained. In addition, when the overall average particle diameter is more than 5.0 μm and the thickness of the sintered body 5 is 90 μm or more and 160 μm or less, no sufficient internal light scattering property is obtained, and the conversion efficiency from blue light to yellow light is low, resulting in a bluish white color. Note that, the overall average particle diameter of the YAG-based particles and the Al₂O₃ particles can be determined by photographing any portion on the surface of the plate-shaped sintered body 5 using a laser microscope or a scanning electron microscope, and subjecting the photographed YAG-based particles and the Al₂O₃ particles to measurement using a linear intercept method without distinguishing between the two particles. At this time, if necessary, thermal etching can be performed to allow the grain boundaries to be observed more clearly.

When the thickness of the sintered body 5 is less than 90 μm, no internal light scattering property is obtained, so that the conversion efficiency from blue light to yellow light is low, resulting in a bluish white color. When the thickness of the sintered body 5 is more than 160 μm, no sufficient luminous flux is obtained.

Note that, the thickness of the sintered body 5 can be measured with a micrometer or by standing the sintered body 5 upright and observing it with an optical microscope.

In the phosphor plate 1 according to the present invention, the YAG-based particles preferably has a concentration of 15 vol % or more and 25 vol % or less with respect to a total amount 100 vol % of the YAG-based particles and the Al₂O₃ particles in the sintered body 5. When the concentration of the YAG-based particles is within the above range, the internal light scattering property in the sintered body 5 can be made more appropriate. The concentration of the YAG-based particles can be determined by calculating a ratio between a YAG phase and an Al₂O₃ phase by performing X-ray diffraction (XRD) on the phosphor plate 1.

In the phosphor plate 1 according to the present invention, the glass coating layer 4 formed only of an inorganic glass coating material is formed on the light exit surface 3 of the sintered body 5. The inorganic glass coating material is, for example, perhydropolysilazane, which is made from a polymer compound that does not contain carbon compounds such as a methyl group or a vinyl group in side chains.

A glass coating layer formed of an organic glass coating material that has been widely used in the conventional art has a problem in heat resistance.

In contrast, the inorganic glass coating material can be used without problems in applications that require higher heat resistance, such as car headlights, and can provide a high luminous flux.

The glass coating layer 4 has a surface roughness Ra (based on JIS B0601:1994) of 0.05 μm or more and 0.4 μm or less on the surface. JP2022-41839A discloses that the surface roughness Ra of the flattened layer formed on one surface of the wavelength conversion element is preferably as small as possible. However, in the case of a very flat surface having a Ra of less than 0.05 μm, a transmittance of blue excitation light increases too much, reducing the conversion efficiency and resulting in a bluish white color.

Therefore, in the present invention, the glass coating layer 4 is provided with an appropriate degree of roughness to prevent a decrease in whiteness (the smaller a deviation from CIE chromaticity coordinates (0.33, 0.33), the higher the whiteness). In the present invention, when the surface roughness Ra of the glass coating layer 4 is 0.05 μm or more and 0.4 μm or less on the surface, the CIE chromaticity coordinates of white light emitted from the surface of the glass coating layer 4 can be brought closer to (0.33, 0.33) (reduction in color unevenness), and light extraction efficiency can be improved.

Note that, the glass coating layer 4 being made from an inorganic glass coating material can be checked based on a C/Si molar ratio value obtained by analyzing a cross section of the glass coating layer 4 by energy dispersive X-ray analysis (EDS). In the case of using an organic glass coating material, for example, organopolysiloxane or organopolysilazane, the C/Si molar ratio is 5 or more, whereas in the case of using an inorganic glass coating material such as perhydropolysilazane, the C/Si molar ratio is 1 or less even when measurement errors such as the use of a carbon tape to fix a sample in the EDS analysis and contamination by hydrocarbons are included.

An average thickness of the glass coating layer 4 is preferably 0.1 μm or more and 3 μm or less, and more preferably 0.3 μm or more and 2 μm or less. With this thickness, the surface roughness Ra of the glass coating layer 4 can be more reliably set to 0.05 μm or more and 0.4 μm or less, and both the light extraction efficiency and the improvement in color unevenness can be achieved.

Note that, the average thickness of the glass coating layer 4 was measured as follows.

Thus, any cross section in a thickness direction of the phosphor plate on which the glass coating layer was formed was imaged using a scanning electron microscope (SEM) with a field of view of 10 μm vertical×12 μm horizontal, an area of the glass coating layer was determined by image processing, this area was then divided by 12 μm to obtain the thickness, the same image was taken at 10 different points, and the average value was used as the average thickness.

The glass coating layer 4 can be formed by using, for example, a spin coating method. In the spin coating method, for example, a uniform polysilazane layer is formed over the entire surface of a substrate by rotating, at a high speed, the sintered body 5 onto which perhydropolysilazane (PHPS) dissolved in an organic solvent has been dropped, and then the substrate is heat-treated (baked) in an oxidizing atmosphere at 400° C. to 500° C. for 50 to 70 minutes to obtain a dense glass coating film.

An example of a method for producing the phosphor plate 1 according to the present invention will be described below.

Yttrium (III) oxide (Y₂O₃), cerium (IV) oxide (CeO₂), gadolinium (III) oxide (Gd₂O₃), and aluminum oxide (Al₂O₃) are mixed and formed into a sheet, which is then degreased and cut out using a press machine to prepare a green formed product having a desired shape. Next, the green formed product is sintered in a vacuum atmosphere of about medium to low vacuum of 1.0×10⁻² Pa or less to obtain the sintered body 5. The sintered body 5 is a sintered body made from YAG-based particles and Al₂O₃ particles.

Next, the surface of the sintered body 5 is subjected to glass coating. As described above, the glass coating is carried out by using, for example, a method such as a spin coating method.

### EXAMPLES

Hereinafter, the present invention will be specifically described based on Examples, but the present invention is not limited to the Examples shown below.

### Example 1

### [Preparation of Chip-Like Phosphor Plate]

(1) Preparation of {(Y_{1-x-y}, Gdₓ, Ce_{y})₃Al₅O₁₂+Al₂O₃} Sintered Body

A raw material powder was obtained by mixing together, at a predetermined mixing ratio, a cerium (IV) oxide powder of 0.4 μm in average particle diameter and 99.9% in purity, an yttrium (III) oxide powder of 1.0 μm in average particle diameter and 99.9% in purity, a gadolinium (III) oxide powder of 0.7 μm in average particle diameter and 99.9% in purity, and an aluminum oxide powder of 0.3 μm in average particle diameter and 99.9% in purity. Thus, weights of the yttrium (III) oxide powder, the gadolinium (III) oxide powder, the cerium (IV) oxide powder, and the aluminum oxide powder were adjusted such that the Gd concentration and the Ce concentration in the {(Y_{1-x-y}, Gdₓ, Ce_{y})₃Al₅O₁₂+Al₂O₃} sintered body 5 were the composition as shown in Table 1.

A slurry was prepared by adding 30 wt % of ethanol, 10 wt % of a polyvinyl butyral (PVB)-based binder, and 3 wt % of a succinic acid-based plasticizer to the raw material powder (100 wt %) and subjecting them to grinding and mixing for 50 hours using a ball mill having aluminum oxide balls.

The slurry was formed into a green sheet having a predetermined thickness by using a doctor blade method. At this time, the thickness of the green sheet to be formed and the number of layers were adjusted such that the obtained sintered body 5 had the thickness shown in Table 1. Specifically, a green sheet having a thickness of 80 μm was prepared, and two of these were laminated.

The obtained green sheet (laminate) was degreased in air at 600° C. for 120 minutes, calcined in air at 1200° C. for 90 minutes, and then sintered in a vacuum atmosphere of 1.0×10² Pa or less at 1680° C. for 360 minutes to obtain the sintered body 5 made from (Y_{1-x-y}, Gdₓ, Ce_{y})₃Al₅O₁₂ particles and the Al₂O₃ particles. Note that, the thickness after sintering was 100 μm due to shrinkage, as shown in Table 1.

### (2) Formation of Glass Coating Layer on Surface of Sintered Body

A mixed solution of perhydropolysilazane and dibutyl ether (SANCELAZANE ANN120-20 manufactured by SANWA KAGAKU CORP.) was uniformly applied onto the surface of the sintered body 5 by using a spin coating method. Thereafter, a baking treatment was carried out at 450° C. for 60 minutes to form the glass coating layer 4 having a thickness of 1.5 μm on the surface of the sintered body 5.

### (3) Cutting

The sintered body 5 on which the glass coating layer 4 was formed was cut into 1 mm×1 mm pieces by dicing, to prepare a chip-like phosphor plate.

### [Evaluation on Chip-Like Phosphor Plate]

### (1) Gd Concentration and Ce Concentration

The Gd concentration (x) and the Ce concentration (y) in the sintered body 5 made from (Y_{1-x-y}, Gdₓ, Ce_{y})₃Al₅O₁₂ particles and Al₂O₃ particles of the chip-like phosphor plate were determined by ICP-AES.

(2) Concentration of (Y_{1-x-y}, Gdₓ, Ce_{y})₃Al₅O₁₂ Particles

The ratio of the YAG phase to the Al₂O₃ phase was calculated by X-ray diffraction (XRD) on the phosphor plate, and the concentration of the (Y_{1-x-y}, Gdₓ, Ce_{y})₃Al₅O₁₂ particles with respect to the total amount (100 vol %) of the (Y_{1-x-y}, Gdₓ, Ce_{y})₃Al₅O₁₂ particles and the Al₂O₃ particles was measured.

(3) Overall Average Particle Diameter of YAG-Based Particles and Al₂O₃Particles

Any portion on the surface of the chip-like phosphor plate facing the surface on which the glass coating layer was not formed was photographed using a laser microscope, and the photographed YAG-based particles and Al₂O₃ particles were subjected to measurement using a linear intercept method without distinguishing between the two particles, to determine the overall average particle diameter of the YAG-based particles and Al₂O₃ particles. The overall average particle diameter shown in Table 1 indicates the average value of the overall average particle diameter obtained by photographing any five different selected portions with a field of view of 150 μm vertical×150 μm horizontal.

### (4) Room Temperature Luminous Flux

The chip-like phosphor plate was fixed onto a blue LED chip (light emitting region: 1 mm square, light emitting wavelength: 450 nm) with a silicone resin. The emitted light was collected using a 4-inch integrating sphere, and the emission spectrum was measured at room temperature using a visible-near infrared fiber multichannel spectrometer (product name USB4000-VIS-NIR-ES, manufactured by Ocean Photonics).

The luminous flux was calculated from the obtained emission spectrum. A commercially available YAG:Ce phosphor (product name P46-Y3, manufactured by Mitsubishi Chemical High-Technica Corporation) powder (20 vol %) was added to a commercially available phenyl silicone (product name OE-6630, manufactured by Dow Corning Corporation) resin on an LED chip of the same type and sealed thereon, the luminous flux at this time was set to 100, and a relative luminous flux value was calculated. A relative luminous flux value of 127 or more was determined to provide bright white light, whereas a value of 121 or less was determined to be insufficient.

### (5) Temperature Characteristic

The chip-like phosphor plate was arranged vertically, horizontally, and diagonally in 3×3 chips using a commercially available phenyl silicone (product name OE-6630, manufactured by Dow Corning Corporation) resin, and set in the center of a 4-inch integrating sphere having a heater, the integrating sphere was irradiated with excitation light in a wavelength range 450 nm±1 nm in the same manner as in fluorescence wavelength measurement, and quantum efficiency was measured at 25° C. and 200° C. from the emission spectrum of the phosphor plate. A value obtained by dividing the quantum efficiency at 200° C. by the quantum efficiency at 25° C. was used as the temperature characteristic. Quantum efficiency of 84 or more was determined to be excellent in temperature dependency of the wavelength conversion efficiency, and quantum efficiency of 81 or less was determined to be poor in temperature dependency of the wavelength conversion efficiency.

### (6) Whiteness

The chip-like phosphor plate was fixed onto a blue LED chip (light emitting region: 1 mm square, light emitting wavelength: 450 nm) with a silicone resin. A chromaticity (CIE_x, CIE_y) of the light emitted from the phosphor plate in a vertical direction (0°) in the CIE 1931 color space was measured. When both ACIE_x and ACIE_y were 0.02 or less for a white chromaticity of (0.33, 0.33), the whiteness was determined to be excellent, and when they were lager than 0.02, the whiteness was determined to be poor.

### [Comprehensive Evaluation]

A case where all of the evaluation items (3) to (5) were excellent was marked with “A”, a case where there was one evaluation item being poor was marked with “B”, and a case where there were two or more evaluation items being poor was marked with “C”. The results are shown in Table 1.

### Examples 2 and 3 Comparative Examples 1 and 2

Chip-like phosphor plates were prepared in the same manner as in Example 1, except that the composition of the raw material powder (the concentration of the gadolinium (III) oxide powder, and the concentration of the cerium (IV) oxide powder) was changed and the Gd concentration and the Ce concentration in the sintered body were changed as shown in Table 1.

The compositions of the phosphor plates and the results of evaluation in the same manner as in Example 1 are shown in Table 1.

It is seen that in Comparative Example 1 having a high Ce concentration, the room temperature luminous flux is small and the brightness of the white light is poor. On the other hand, in Comparative Example 2 having a high Gd concentration, the temperature dependency of the wavelength conversion efficiency from room temperature to 200° C. (temperature characteristic, i.e., the luminous flux at a high temperature) is poor.

### Examples 4 and 5 Comparative Examples 3 and 4

Chip-like phosphor plates were prepared in the same manner as in Example 1, except that the concentration of the (Y_{1-x-y}, Gdₓ, Ce_{y})₃Al₅O₁₂ particles with respect to the total amount (100 vol %) of the (Y_{1-x-y}, Gdₓ, Ce_{y})₃Al₅O₁₂ particles and the Al₂O₃ particles was changed as shown in Table 1.

The compositions of the phosphor plates and the results of evaluation in the same manner as in Example 1 are shown in Table 1.

In Comparative Example 3 having a concentration of the (Y_{1-x-y}, Gdₓ, Ce_{y})₃Al₅O₁₂ particles of less than 15 vol %, the internal scattering increases and thus the brightness decreases, and in Comparative Example 4 having a concentration of the (Y_{1-x-y}, Gdₓ, Ce_{y})₃Al₅O₁₂ particles of more than 25 vol %, the internal scattering decreases and thus the whiteness is poor.

### Examples 6 to 8 Comparative Examples 5 and 6

Phosphor plates were prepared in the same manner as in Example 1, except that the thickness of the green sheet formed by using the doctor blade method was changed, and the thickness of the sintered body was changed as shown in Table 1.

The compositions of the phosphor plates and the results of evaluation in the same manner as in Example 1 are shown in Table 1.

In Comparative Example 5 having a thickness of the sintered body of less than 90 μm, bright white light is obtained, but the whiteness is poor. On the other hand, in Comparative Example 6 having a thickness of the sintered body of more than 160 μm, the brightness is poor.

### Examples 9 and 10 Comparative Examples 7 and 8

Phosphor plates were prepared in the same manner as in Example 1, except that the sintering temperature and time were changed, and the overall average particle diameter of the sintered body was changed as shown in Table 1.

The compositions of the phosphor plates and the results of evaluation in the same manner as in Example 1 are shown in Table 1.

In Comparative Example 7 having an overall average particle diameter of the sintered body of less than 3.0 μm, no sufficient luminous flux is obtained. On the other hand, in Comparative Example 8 having an overall average particle diameter of the sintered body of more than 5.0 μm, no sufficient internal light scattering property is obtained, and the conversion efficiency from blue light to yellow light is low, resulting in a bluish white color.

### Comparative Example 9

A phosphor plate was prepared in the same manner as in Example 1, except that the raw material for forming the glass coating layer 4 was changed from perhydropolysilazane as an inorganic glass coating material to organopolysilazane (SANCELAZANE, product name #2000-20, manufactured by SANWA KAGAKU CORP.) as an organic glass coating material in Comparative Example 9. The composition of the phosphor plate and the results of evaluation in the same manner as in Example 1 are shown in Table 1.

In Comparative Example 9 in which the glass coating layer 4 is formed using organopolysilazane, which is an organic glass coating material, (C/Si molar ratio on cross section: 7.0), the heat resistance is poor, the film is peeled off during use, and the brightness of the white light is poor.

### Comparative Example 10

A phosphor plate was prepared in the same manner as in Example 1, except that the spin coating was repeated three times. The composition of the phosphor plate and the results of evaluation in the same manner as in Example 1 are shown in Table 1. In Comparative Example 10 in which the surface roughness Ra of the glass coating layer 4 is 0.01 μm on the surface, which is small, a slightly bluish white color is obtained.

### Example 11

A phosphor plate was prepared in the same manner as in Example 1, except that the spin coating was repeated twice.

The composition of the phosphor plate and the results of evaluation in the same manner as in Example 1 are shown in Table 1. In the phosphor plate in Example 11 in which the surface roughness Ra of the glass coating layer 4 is 0.05 μm on the surface, which is larger than 0.01 μm in Comparative Example 10, the room temperature luminous flux is high, the temperature characteristic is good, and the whiteness is also high, as in the other Examples.

### Example 12

A phosphor plate was prepared in the same manner as in Example 1, except that the ratio of perhydropolysilazane was set to 2/3 in the mixed solution of perhydropolysilazane and dibutyl ether.

The composition of the phosphor plate and the results of evaluation in the same manner as in Example 1 are shown in Table 1.

In the phosphor plate in Example 10 in which the surface roughness Ra of the glass coating layer 4 is 0.40 μm on the surface, which is smaller than 0.41 μm in Comparative Example 11 to be described later, the room temperature luminous flux is high, the temperature characteristic is good, and the whiteness is also high, as in the other Examples.

### Comparative Example 11

A phosphor plate was prepared in the same manner as in Example 2, except that the ratio of perhydropolysilazane was halved in the mixed solution of perhydropolysilazane and dibutyl ether.

The composition of the phosphor plate and the results of evaluation in the same manner as in Example 1 are shown in Table 1.

In Comparative Example 11 in which the surface roughness Ra is 0.41 μm, which is larger than 0.020 μm, the emitted light is largely scattered, and the luminous flux is insufficient.

### Reference Example

A phosphor plate having a thickness of 200 μm was prepared as Conventional Example using a ((Y_{1-x-y}, Gdₓ, Ce_{y})₃Al₅O₁₂+Al₂O₃) (x=0.070 and y=0.012) sintered body (corresponding to JP2022-104527A) without providing the glass coating layer 4, and the evaluation was carried out in the same manner as in Example 1.

As shown in Table 1, the phosphor plate in Reference Example has poorer room temperature luminous flux and temperature characteristic than the phosphor plates according to the present invention.

According to the above experiments, it has been found that the phosphor plate according to the present invention can provide a higher flux and excellent whiteness in a white light LED.

TABLE 1

| | Sintered body | | | | | |
|---|---|---|---|---|---|---|
| | | | YAG | | | |
| | | | particles/(YAG | | Overall | |
| | | | particles + | | average | |
| | Gd | Ce | Al₂O₂ | | particle | |
| | concentration | concentration | particles) ratio | Thickness | diameter | Glass coating layer |
| | x | y | [vol %] | [μm] | [μm] | Coating material |
| Comparative | 0.015 | 0.027 | 20 | 100 | 4.2 | Perhydropolysilazane |
| Example 1 | | | | | | |
| Example 2 | 0.018 | 0.025 | 20 | 100 | 4.1 | Perhydropolysilazane |
| Example 1 | 0.036 | 0.020 | 20 | 100 | 4.0 | Perhydropolysilazane |
| Example 3 | 0.054 | 0.018 | 20 | 100 | 3. [symbol] | Perhydropolysilazane |
| Comparative | 0.057 | 0.016 | 20 | 100 | 3.8 | Perhydropolysilazane |
| Example 2 | | | | | | |
| Comparative | 0.036 | 0.020 | 12 | 100 | 4.0 | Perhydropolysilazane |
| Example 3 | | | | | | |
| Example 4 | 0.036 | 0.020 | 16 | 100 | 4.0 | Perhydropolysilazane |
| Example 5 | 0.036 | 0.020 | 25 | 100 | 4.0 | |
| Comparative | 0.036 | 0.020 | 28 | 100 | 4.0 | Perhydropolysilazane |
| Example 4 | | | | | | |
| Comparative | 0.036 | 0.020 | 20 | 70 | 4.0 | Perhydropolysilazane |
| Example 5 | | | | | | |
| Example 6 | 0.036 | 0.020 | 20 | 90 | 4.0 | Perhydropolysilazane |
| Example 7 | 0.036 | 0.020 | 20 | 120 | 4.0 | Perhydropolysilazane |
| Example 8 | 0.036 | 0.020 | 20 | 1 [symbol] 0 | 4.0 | Perhydropolysilazane |
| Comparative | 0.036 | 0.020 | 20 | 180 | 4.0 | Perhydropolysilazane |
| Example 6 | | | | | | |
| Comparative | 0.036 | 0.020 | 20 | 100 | 2.5 | Perhydropolysilazane |
| Example 7 | | | | | | |
| Example 9 | 0.036 | 0.020 | 20 | 100 | 3.0 | Perhydropolysilazane |
| Example 10 | 0.036 | 0.020 | 20 | 100 | 5.0 | Perhydropolysilazane |
| Comparative | 0.036 | 0.020 | 20 | 100 | 5. [symbol] | Perhydropolysilazane |
| Example 8 | | | | | | |
| Comparative | 0.040 | 0.020 | 20 | 100 | 4.0 | Organopolys [symbol] |
| Example 9 | | | | | | |
| Comparative | 0.036 | 0.020 | 20 | 100 | 4.0 | Perhydropolysilazane |
| Example 10 | | | | | | |
| Example 11 | 0.036 | 0.020 | 20 | 100 | 4.0 | Perhydropolysilazane |
| Example 12 | 0.036 | 0.020 | 20 | 100 | 4.0 | Perhydropolysilazane |
| Comparative | 0.036 | 0.020 | 20 | 100 | 4.0 | Perhydropolysilazane |
| Example 11 | | | | | | |
| Reference | 0.070 | 0.012 | 20 | 200 | 4.0 | — |
| Example | | | | | | |

| | Glass coating layer | | | | | |
|---|---|---|---|---|---|---|
| | | Surface | | | | |
| | | roughness | Evaluation | | | |
| | | Ra on | Room | | | |
| | C/Si | emission | temperature | Temperature | | |
| | molar | surface | luminous | characteristic | Whiteness | Comprehensive |
| | ratio | [μm] | flux | (200° C./RT) | (CIE_x, CIE_y) | evaluation |
| Comparative | 0.5 | 0.10 | 118 | 88 | (0.3421, 0.3497) | B |
| Example 1 | | | | | | |
| Example 2 | 0.5 | 0.10 | 128 | 84 | (0.3352, 0.3459) | A |
| Example 1 | 0.5 | 0.10 | 127 | 84 | (0.3275, 0.3222) | A |
| Example 3 | 0.5 | 0.10 | 126 | 84 | (0.319 [symbol] , 0.3301) | A |
| Comparative | 0.5 | 0.10 | 127 | 81 | (0.3171, 0.3129) | B |
| Example 2 | | | | | | |
| Comparative | 0.5 | 0.10 | 120 | 84 | (0.3482, 0.3425) | B |
| Example 3 | | | | | | |
| Example 4 | 0.5 | 0.10 | 124 | 84 | (0.3411, 0.3388) | A |
| Example 5 | 0.5 | 0.10 | 127 | 84 | (0.3169, 0.3201) | A |
| Comparative | 0.5 | 0.10 | 129 | 84 | (0.3032, 0.3100) | B |
| Example 4 | | | | | | |
| Comparative | 0.5 | 0.10 | 130 | 84 | (0.3094, 0.3140) | B |
| Example 5 | | | | | | |
| Example 6 | 0.5 | 0.10 | 129 | 84 | (0.3230, 0.3211) | A |
| Example 7 | 0.5 | 0.10 | 127 | 84 | (0.33 [symbol] 6, 0.3259) | A |
| Example 8 | 0.5 | 0.10 | 126 | 84 | (0.3391, 0.33 [symbol] 3) | A |
| Comparative | 0.5 | 0.10 | 119 | 84 | (0.3459, 0.3480) | B |
| Example 6 | | | | | | |
| Comparative | 0.5 | 0.10 | 119 | 84 | (0.3488, 0.3385) | B |
| Example 7 | | | | | | |
| Example 9 | 0.5 | 0.10 | 123 | 84 | (0.3315, 0.3286) | A |
| Example 10 | 0.5 | 0.10 | 128 | 84 | (0.3210, 0.3186) | A |
| Comparative | 0.5 | 0.10 | 130 | 84 | (0.3156, 0.30 [symbol] 9) | B |
| Example 8 | | | | | | |
| Comparative | 7.0 | 0.10 | 118 | 84 | (0.3284, 0.3281) | B |
| Example 9 | | | | | | |
| Comparative | 0.5 | 0.01 | 129 | 84 | (0.3141, 0.3107) | B |
| Example 10 | | | | | | |
| Example 11 | 0.5 | 0.05 | 129 | 84 | (0.3182, 0.3177) | A |
| Example 12 | 0.5 | 0.40 | 126 | 84 | (0.3442, 0. [symbol] 331) | A |
| Comparative | 0.5 | 0.41 | 118 | 84 | (0.3419, 0.3411) | B |
| Example 11 | | | | | | |
| Reference | No | | 110 | 80 | (0.3291, 0.3255) | C |
| Example | | | | | | |

[symbol]

indicates data missing or illegible when filed

What is claimed is:

1. A phosphor plate comprising:
a plate-shaped sintered body having a light incident surface that is to receive light from a light source and a light exit surface that is disposed opposite to the light incident surface and that is to emit the light received at the light incident surface; and
a glass coating layer provided at the light exit surface of the sintered body, wherein
the sintered body comprises (Y_{1-x-y}, Gdₓ, Ce_{y})₃Al₅O₁₂ particles, where x and y fall within ranges 0.018≤x≤0.054 and 0.018≤y≤0.025, and Al₂O₃ particles,
the (Y_{1-x-y}, Gdₓ, Ce_{y})₃Al₅O₁₂ particles and the Al₂O₃ particles have an overall average particle diameter of 3.0 μm or more and 5.0 μm or less,
the (Y_{1-x-y}, Gdₓ, Ce_{y})₃Al₅O₁₂ particles have a concentration of 15 vol % or more and 25 vol % or less with respect to a total amount 100 vol % of the (Y_{1-x-y}, Gdₓ, Ce_{y})₃Al₅O₁₂ particles and the Al₂O₃ particles,
the sintered body has a thickness of 90 μm or more and 160 μm or less,
the glass coating layer is formed from an inorganic glass coating material, and
a surface of the glass coating layer has a surface roughness Ra of 0.05 μm or more and 0.4 μm or less.
